(19) United States
(12) Patent Application Publication
(10) Pub. No.: US 2021/0111131 A1
(43) Pub. Date: Apr. 15, 2021

(54) CONFORMAL SHIELD FOR BLOCKING LIGHT IN AN INTEGRATED CIRCUIT PACKAGE

(71) Applicant: Cirrus Logic International Semiconductor Ltd., Edinburgh (GB)

(72) Inventors: John PAVELKA, Austin, TX (US); David PATTEN, Austin, TX (US)

(73) Assignee: Cirrus Logic International Semiconductor Ltd., Edinburgh (GB)

(21) Appl. No.: 17/028,707

(22) Filed: Sep. 22, 2020

Related U.S. Application Data
(60) Provisional application No. 62/915,373, filed on Oct. 15, 2019.

(51) Int. Cl. H01L 23/552; H01L 23/00

(52) U.S. Cl. CPC H01L 23/552; H01L 21/28568; H01L 24/13

(57) ABSTRACT

A semiconductor device may include an integrated circuit die and a thin metal layer applied and conformed to one or more surfaces of the integrated circuit die in order to shield active circuitry of the integrated circuit die from light.

### RELATED APPLICATION

The present disclosure claims priority to U.S. Provisional Patent Application Ser. No. 62/915,373, filed Oct. 15, 2019, which is incorporated by reference herein in its entirety.

### FIELD OF DISCLOSURE

The present disclosure relates in general to semiconductor fabrication, and more particularly, to forming a conformal shield for blocking light in integrated circuit packages, including wafer-level chip-scale packages.

### BACKGROUND

Semiconductor device fabrication is a process used to create integrated circuits that are present in many electrical and electronic devices. Semiconductor device fabrication comprises a multiple-step sequence of photolithographic, mechanical, and chemical processing steps during which electronic circuits are gradually created on a wafer made of semiconducting material. For example, during semiconductor device fabrication, numerous discrete circuit components, including transistors, resistors, capacitors, inductors, and diodes, may be formed on a single semiconductor die.

For years, integrated circuits have been fabricated using complementary metal-oxide-semiconductor (CMOS) devices. CMOS devices are sensitive to light, both visible and infrared. Exposure to light may interrupt circuit function, causing a CMOS device to malfunction. CMOS devices are often sealed in plastic or ceramic packages which block light from reaching the die. However, with the trend towards miniaturization, many devices are now being assembled in wafer-level chip-scale packages (WLCSP) which may expose the bare die to environmental light. Generally speaking, fabrication of a WLCSP involves packaging an integrated circuit while the integrated circuit is still part of a semiconductor wafer, in contrast to the more conventional method of slicing the wafer into individual circuits (dice) and then packaging the dice individually. Thus, the resulting package may be practically of the same size as the die. A major application area of WLCSPs is smartphones and similar mobile devices due to size constraints of such devices. For example, functions provided by WLCSPs in smartphones may include sensors, power management, wireless communication, amplifiers, and others.

If a WLCSP device is exposed to certain wavelengths of light while it is operating, its circuit function may be adversely affected. Silicon, often used in the fabrication of CMOS devices, is transparent to many wavelengths of light, including infrared wavelengths, allowing light to penetrate silicon to reach light-sensitive CMOS circuitry, which may lead to circuit malfunction. As shown in FIG. 1, current approaches for blocking light from a WLCSP die 2 (including traditional features such as a redistribution layer 8 and a plurality of bumps 10) may include adding an opaque film laminate 4 to the back of the device (also referred to as “backside coating” or “backside film”), applying a mold compound 6 to the back of the device and/or the four side walls of the device (also referred to as “eWLCSP”), or simply encapsulating the entire WLCSP device in epoxy or similar material (also referred to as “glob top”). All of these existing approaches use organic materials (typically epoxy based) which are only semi-opaque to wavelengths of light in the visible and infrared spectrums. To achieve sufficient blocking of light (e.g., 95% or more), the material must be relatively thick (e.g., on the order 100 μm thick per side). This material thickness used for light shielding adds significant size to smaller devices which are constrained in the space available to them within the device. Even at these material thicknesses, one hundred percent (100%) blocking of problem wavelengths of light is not achieved.

Mobile phones and tablets have added a variety of optical sensors (face recognition, cameras, ambient light sensors, etc). Surrounding these sensors are CMOS devices that may have their function affected by exposure to light. At the same time, the mobile phone and tablet manufacturers are pushing for a reduction in device height and body size so that they may fit more devices into tighter spaces. Traditional light shielding solutions all add significant size and height to the devices and fail to block 100% of the incident light.

### SUMMARY

In accordance with the teachings of the present disclosure, certain disadvantages and problems associated with blocking incident light in an integrated circuit package may be reduced or eliminated.

In accordance with embodiments of the present disclosure, an optical shield for a semiconductor device may include a thin metal layer applied and conformed to one or more surfaces of the semiconductor device in order to shield active circuitry of the semiconductor device from light.

In accordance with these and other embodiments of the present disclosure, a method for fabricating an optical shield for a semiconductor device may include applying and conforming a thin metal layer to one or more surfaces of the semiconductor device in order to shield active circuitry of the semiconductor device from light.

In accordance with these and other embodiments of the present disclosure, a semiconductor device may include an integrated circuit die and a thin metal layer applied and conformed to one or more surfaces of the integrated circuit die in order to shield active circuitry of the integrated circuit die from light.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are explanatory examples and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a side cross-sectional elevation view of a portion of an integrated circuit die, in accordance with the prior art;

FIG. 2 illustrates a side cross-sectional elevation view of a sputtering chamber, in accordance with embodiments of the present disclosure;

FIG. 3 illustrates a side cross-sectional elevation view of a portion of an example integrated circuit die having backside metal shielding and side wall metal shielding, in accordance with embodiments of the present disclosure; and

FIG. 4 illustrates a side cross-sectional elevation view of a portion of an example integrated circuit die having side wall metal shielding and a non-metal backside coating, in accordance with embodiments of the present disclosure.

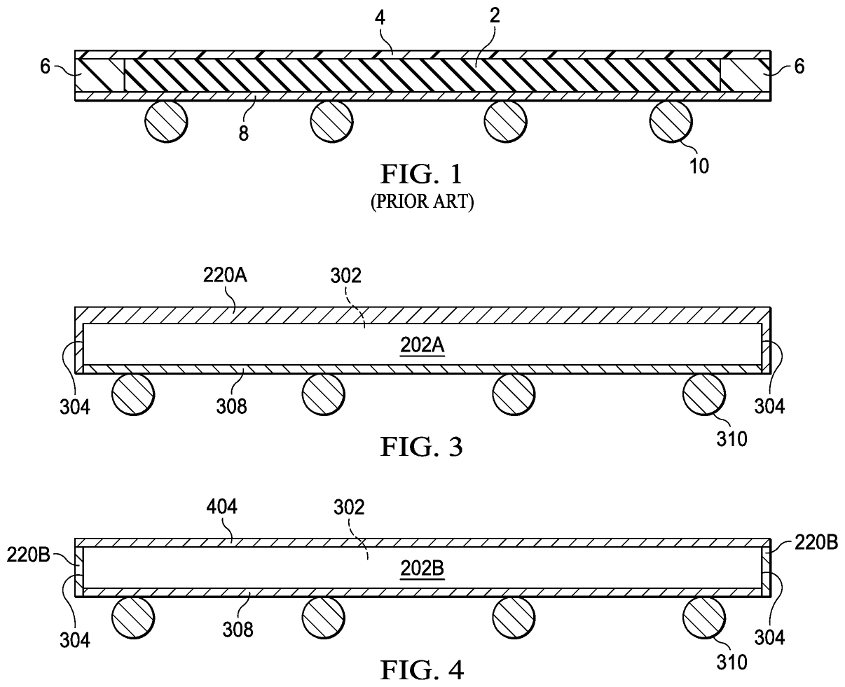

### DETAILED DESCRIPTION

Embodiments of the present disclosure may provide conformal metal light shielding for a semiconductor device and/or its package. Embodiments of the present disclosure may provide near to full one hundred percent (100%) light blocking performance, while generally only adding one to two micrometers to the body size and height of a semiconductor device. The optical shield for the semiconductor device may have a thin metal layer applied and conformed to one or more surfaces of the semiconductor device. The optical shield may protect active circuitry of the semiconductor device from being exposed to light. The thin metal layer may comprise one or more of the following metals: aluminum, copper, stainless steel, nickel, titanium, and/or gold. The thin metal layer may be formed by sputtering or plating. The thin metal layer may be at least 0.2 μm in thickness.

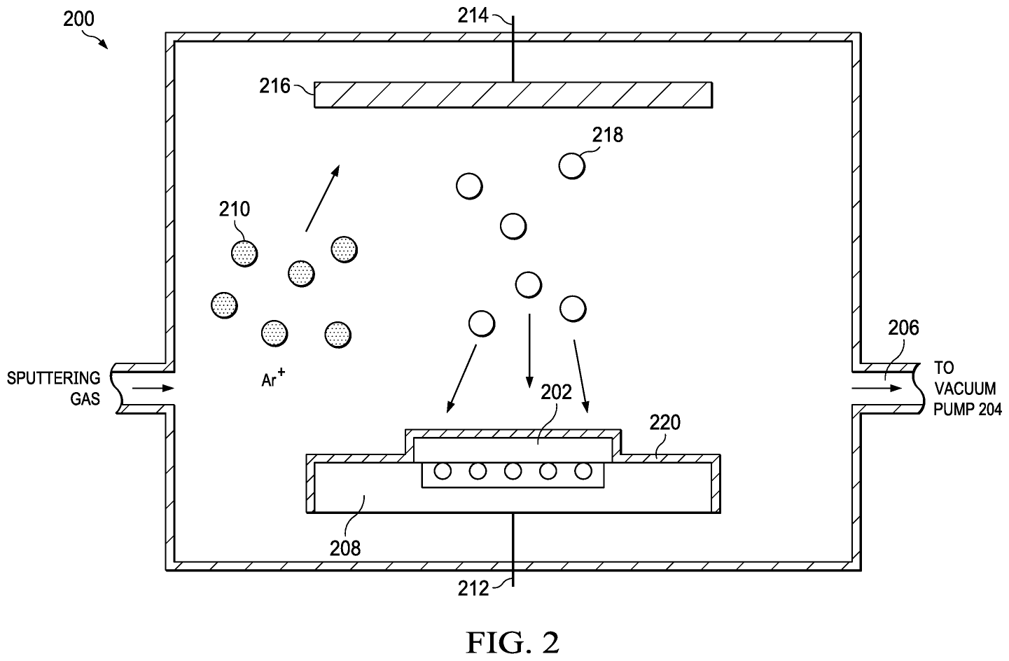

FIG. 2 illustrates a side cross-sectional elevation view of a sputtering chamber 200, in accordance with embodiments of the present disclosure. As described in greater detail below, sputtering chamber 200 may be used to sputter a metallic light shield onto one or more surfaces of an integrated circuit die 202 (e.g., a WLCSP die), in accordance with embodiments of the present disclosure.

To create a metallic light shield for integrated circuit die 202, integrated circuit die 202 may be fabricated and processed in accordance with heretofore known techniques, except as otherwise described herein. Integrated circuit die 202 may then (along with other integrated circuit dies) be fixtured and placed into sputtering chamber 200.

As shown in FIG. 2, sputtering chamber 200 may be coupled to a vacuum pump 204 at a fluidic outlet 206 of sputtering chamber 200. Integrated circuit die 202 may be placed on a fixture 208 to hold integrated circuit die 202 in place. A sputtering gas (e.g., argon or other suitable gas) may be introduced into sputtering chamber 200 at a fluidic inlet of sputtering chamber 200. Radio-frequency electrical energy may be applied between an anode 212 and a cathode 214 to convert the sputtering gas into an electrically-charged plasma 210. Positively-charged ions of the sputtering gas plasma may be accelerated towards a metal sputtering target 216 electrically coupled to cathode 214 which may be held at a negative electrical potential by cathode 214. Metal sputtering target 216 may comprise any suitable metal (e.g., aluminum, copper, titanium, nickel, gold, stainless steel, etc., with selection of the metal used based on corrosion resistance, materials compatibility for the intended application, and/or other suitable factors). When these positively-charged ions impact sputtering target 216, the positively-charged ions may dislodge atoms 218 of sputtering target 216. Atoms 218 may accumulate on integrated circuit die 202 to deposit a thin metal film 220 (e.g., at least 0.2 μm in thickness) on integrated circuit die 202 held by fixture 208. Such metal film 220 may conform to all exposed surfaces of integrated circuit die 202. Further, unlike a metal redistribution layer of integrated circuit die 202 that couples to electrically-conductive bumps of integrated circuit die 202, metal film 220 may be unpatterned.

Although FIG. 2 depicts depositing of metal film 220 on five surfaces of integrated circuit die 202 (e.g., backside and four side walls), in some embodiments, not all of such five surfaces may have metal film 220 deposited thereon. For example, in some embodiments, metal film 220 may only be deposited on the four side walls of integrated circuit die 202. In yet other embodiments, metal film 220 may be deposited on one or more but fewer than the four side walls of integrated circuit die 202.

Alternatively to the sputtering process described above, metal film 220 may be deposited using a plating process. Such plating process may be facilitated by first depositing a thin seed layer of metal, such as titanium, then using either electroless-plating or electro-plating to deposit the bulk of metal film 220.

After metal deposition, integrated circuit die 202 may be removed from the fixture 208 and sputtering chamber 200 and placed in appropriate media for shipping or further processing/testing (e.g., carrier tape, tray, etc).

Use of metal film 220 to shield integrated circuit die 202 may have numerous advantages to traditional approaches. For example, metals may have a much denser structure than organic materials and therefore more effectively block light. At a wavelength of 940 nm, less than a one-μm thickness of metal may block nearly 100% of incident light, while a 100-μm thickness of mold compound may block only 95% of incident light. Thus, using a metal film to block light from integrated circuit die 202 may be significantly more effective than using traditional epoxy-based materials. This use of metal shielding may also allow an effective shield from incident light to be created while only minimally increasing the effective size of integrated circuit die 202.

Experimental measurements indicate that metal films as thin as 0.2 μm may be sufficient to block more than 99% of incident light. However, for practical applications, a desired metal thickness for metal film 220 may be in the range of 1 μm-5 μm to assure complete coverage of surface(s) of integrated circuit die 202. Such thicker films may be more tolerant of surface contaminants, such as dust, which may create pin-holes in thinner metal films. Thicker films may also be more suitable for marking processes, such as laser marking, where some portion of metal film 220 may be removed through ablation or another process to create the marked characters.

FIG. 3 illustrates a side cross-sectional elevation view of a portion of an example integrated circuit die 202A having a metal film 220A deposited on a backside surface 302 of integrated circuit die 202A (e.g., a surface parallel to and opposite of the “topside” surface upon which a metal redistribution layer 308 and solder bumps 310 are formed) and deposited on all four sidewall surfaces 304 of integrated circuit die 202A (e.g., surface perpendicular to the topside surface and backside surface 302). Due to the cross-sectional nature of FIG. 3, metal film 220A is shown only on two sidewall surfaces 304.

FIG. 4 illustrates a side cross-sectional elevation view of a portion of an example integrated circuit die 202B having a backside film 404 made of organic material formed on a backside surface 302 of integrated circuit die 202B (e.g., a surface parallel to and opposite of the “topside” surface upon which a metal redistribution layer 308 and solder bumps 310 are formed) and having a metal film 220B deposited on all four sidewall surfaces 304 of integrated circuit die 202B (e.g., surface perpendicular to the topside surface and backside surface 302). Due to the cross-sectional nature of FIG. 4, metal film 220B is shown only on two sidewall surfaces 304.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An optical shield for a semiconductor device, comprising:
a thin metal layer applied and conformed to one or more surfaces of the semiconductor device in order to shield active circuitry of the semiconductor device from light.

2. The optical shield of claim 1, wherein:
the one or more surfaces of the semiconductor device comprise a backside surface of the semiconductor device parallel to and opposite of a topside surface of the semiconductor device upon which a metal redistribution layer and electrically-conductive bumps are formed; and
the thin metal layer is unpatterned.

3. The optical shield of claim 1, wherein the one or more surfaces of the semiconductor device comprise at least one sidewall surface of the semiconductor device perpendicular to a topside surface of the semiconductor device upon which a metal redistribution layer and electrically-conductive bumps are formed.

4. The optical shield of claim 3, wherein:
a backside surface of the semiconductor device has formed thereon a backside film made of organic material; and
the backside surface is parallel to and opposite of a topside surface of the semiconductor device upon which a metal redistribution layer and electrically-conductive bumps are formed.

5. The optical shield of claim 1, wherein the thin metal layer comprises one among the following metals: aluminum, copper, stainless steel, nickel, titanium, and gold.

6. The optical shield of claim 1, wherein the thin metal layer is formed by one of sputtering and plating.

7. The optical shield of claim 1, wherein the thin metal layer is at least 0.2 micrometer in thickness.

8. A method for fabricating an optical shield for a semiconductor device, comprising:
applying and conforming a thin metal layer to one or more surfaces of the semiconductor device in order to shield active circuitry of the semiconductor device from light.

9. The method of claim 8, wherein:
the one or more surfaces of the semiconductor device comprise a backside surface of the semiconductor device parallel to and opposite of a topside surface of the semiconductor device upon which a metal redistribution layer and electrically-conductive bumps are formed; and
the thin metal layer is unpatterned.

10. The method of claim 8, wherein the one or more surfaces of the semiconductor device comprise at least one sidewall surface of the semiconductor device perpendicular to a topside surface of the semiconductor device upon which a metal redistribution layer and electrically-conductive bumps are formed.

11. The method of claim 10, wherein:
a backside surface of the semiconductor device has formed thereon a backside film made of organic material; and
the backside surface is parallel to and opposite of a topside surface of the semiconductor device upon which a metal redistribution layer and electrically-conductive bumps are formed.

12. The method of claim 8, wherein the thin metal layer comprises one among the following metals: aluminum, copper, stainless steel, nickel, titanium, and gold.

13. The method of claim 8, wherein the thin metal layer is formed by one of sputtering and plating.

14. The method of claim 8, wherein the thin metal layer is at least 0.2 micrometer in thickness.

15. A semiconductor device, comprising:
an integrated circuit die; and
a thin metal layer applied and conformed to one or more surfaces of the integrated circuit die in order to shield active circuitry of the integrated circuit die from light.

16. The semiconductor device of claim 15, wherein:
the one or more surfaces of the integrated circuit die comprise a backside surface of the integrated circuit die parallel to and opposite of a topside surface of the integrated circuit die upon which a metal redistribution layer and electrically-conductive bumps are formed; and
the thin metal layer is unpatterned.

17. The semiconductor device of claim 15, wherein the one or more surfaces of the integrated circuit die comprise at least one sidewall surface of the integrated circuit die perpendicular to a topside surface of the integrated circuit die upon which a metal redistribution layer and electrically-conductive bumps are formed.

18. The semiconductor device of claim 17, wherein:
a backside surface of the integrated circuit die has formed thereon a backside film made of organic material; and
the backside surface is parallel to and opposite of a topside surface of the integrated circuit die upon which a metal redistribution layer and electrically-conductive bumps are formed.

19. The semiconductor device of claim 15, wherein the thin metal layer comprises one among the following metals: aluminum, copper, stainless steel, nickel, titanium, and gold.

20. The semiconductor device of claim 15, wherein the thin metal layer is formed by one of sputtering and plating.

21. The semiconductor device of claim 15, wherein the thin metal layer is at least 0.2 micrometer in thickness.
